(19) United States
(12) Patent Application Publication
(10) Pub. No.: US 2026/0254190 A1
(43) Pub. Date: Aug. 27, 2026

(54) LASER DEVICE, OPTICAL CIRCUIT SYSTEM, SENSING SYSTEM, LASER LIGHT GENERATING UNIT, AND METAMATERIAL

(71) Applicant: Sony Group Corporation, Tokyo (JP)

(72) Inventor: Chih-Zong DENG, Kanagawa (JP)

(21) Appl. No.: 18/992,019

(22) PCT Filed: Sep. 29, 2022
(86) PCT No.: PCT/JP2022/036448

§ 371 Date: Jan. 7, 2025

(51) Int. Cl. H01S 3/16

(52) U.S. Cl. CPC H01S 3/163

(57) ABSTRACT

An object of the present disclosure is to provide a laser that can oscillate laser light in an infrared region (for example, light in a communication wavelength band) and that has a low laser oscillation threshold value and reduces an optical loss.

The present disclosure provides a laser device including a laser light generating unit having a nanostructure configured to exhibit a BIC mode and including a perovskite material, the laser light generating unit being configured to oscillate infrared light. The nanostructure may be configured to exhibit a zero refractive index. For example, the nanostructure may be formed by the perovskite material, or the nanostructure may be formed by a dielectric material, and provided in the perovskite material.

### TECHNICAL FIELD

The present disclosure relates to a laser device, a photonic system, a sensing system, a laser light generating unit, and a metamaterial. More particularly, the present disclosure relates to a laser device including a laser light generating unit having a specific nanostructure, a photonic system and a sensing system having the laser device, the laser light generating unit, and a metamaterial having the nanostructure.

### BACKGROUND ART

A nanolaser and a microlaser are very important optical elements used as a light source in an optical circuit (for example, an optical chip). A few proposals have thus far been made with regard to such very small lasers. For example, the following NPL 1 proposes a cavity-free laser using a Dirac-cone zero-index material (DCZIM), which is a kind of zero refractive index material. In the laser, an optical amplifying device (cavity proper) is formed by a zero refractive index material, and therefore, a component size is not limited according to a specific wavelength. As a result, a degree of freedom in design of the optical amplifying device is improved, and miniaturization and on-chip implementation of laser parts become possible.

### CITATION LIST

### Patent Literature

### [NPL 1]

Y. Peng and S. Liao, “ZIM Laser: Zero-Index-Materials Laser,” IEEE Journal on Multiscale and Multiphysics Computational Techniques, vol. 4, pp. 133-142, 2019

### SUMMARY

### Technical Problem

Main constituent elements of a laser include two parts, that is, a cavity (resonator) and a gain medium. For the gain medium of these parts, the use of a perovskite material as a material that realizes light absorption and radiation with a high efficiency and a low threshold value has been proposed. As the cavity, a photonic crystal, a plasmonic resonator, and the like have been reported. With regard to the photonic crystal cavity, an out-of-plane radiation loss can be a problem, or an out-of-plane radiation loss of DCZIM, for example, can be a problem. In addition, the photonic crystal cavity presents another problem of process complexity at a time of integration with an optical circuit such as a waveguide. In addition, problems of the plasmonic resonator are a low quality coefficient Q and a difficulty in realizing a single mode.

In addition, a laser using a bound state in continuum mode (BIC mode) has been reported. The BIC mode can theoretically achieve a zero radiation loss and an infinite quality coefficient Q by a nanostructure designed, so that the refractive index of a material and geometry thereof satisfy predetermined conditions. However, researches into the optical BIC mode are in a germinal stage. For example, a laser using the BIC mode has a problem of having a large element area. In addition, it is considered to be preferable to investigate into applicability of the laser using the BIC mode to a communication wavelength band (near-infrared region). In addition, it is also considered to be preferable to enable the laser using the BIC mode to oscillate on a chip (in-plane).

In light of the above, it is an object of the present disclosure to provide a laser device that is able to oscillate laser light in an infrared region (for example, light in a communication wavelength band) and reduces an optical loss.

In addition, it is also preferable to lower a laser oscillation threshold value of the laser device. Further, it is also preferable to raise the Q-value of the laser device. In addition, it is also preferable to reduce the element area of the laser. In addition, it is also preferable that the laser be able to be integrated with an optical circuit easily. In a few aspects, the present disclosure has another object of addressing one or more of these problems.

In NPL 1 described above, a cavity-free laser using the zero refractive index material has been proposed. However, the zero refractive index material described in the document has a pillar type structure. The structure is mechanically fragile, and further contrivance is considered to be necessary in order to integrate the laser into an optical circuit. In addition, the document indicates that there is a theoretically possible mode for the laser, but does not consider an actual oscillating function of the laser.

### Solution to Problem

The present disclosure provides a laser device including a laser light generating unit having a nanostructure configured to exhibit a BIC mode and including a perovskite material, the laser light generating unit being configured to oscillate infrared light.

The nanostructure may be configured to exhibit a zero refractive index.

The nanostructure may be formed by the perovskite material, or the nanostructure may be formed by a dielectric material, and provided in the perovskite material.

The nanostructure may be a structure in which structural units having air holes are arranged one-dimensionally or two-dimensionally.

In one embodiment, the nanostructure may be a structure in which structural units having air holes are arranged two-dimensionally, the air holes may have a radius of 10 to 300 nm, and the air holes may have an arrangement period of 100 to 1000 nm.

In one embodiment, the nanostructure may be a structure in which structural units having air holes are arranged one-dimensionally, the air holes may have a radius of 10 to 300 nm, and the air holes may have an arrangement period of 100 to 1000 nm.

The laser light generating unit may have a substrate and a gain medium layer provided on the substrate, and the gain medium layer may have the nanostructure.

The laser light generating unit may have a substrate and a gain medium layer provided on the substrate, the gain medium layer may have the nanostructure, and the gain medium layer may have a thickness of 100 to 1500 nm.

The perovskite material may be an organic-inorganic perovskite material.

The BIC mode may be a BIC mode of a resonance-trapped type or a BIC mode of a symmetry-protected type. The laser device may be a laser device of an in-plane type.

The laser device may be a laser device of an out-of-plane type.

In addition, the present disclosure also provides an optical circuit system including the laser device.

In addition, the present disclosure also provides a sensing system including the laser device.

In addition, the present disclosure also provides a laser light generating unit having a nanostructure configured to exhibit a BIC mode and including a perovskite material, the laser light generating unit being configured to oscillate infrared light.

In addition, the present disclosure also provides a metamaterial having a nanostructure configured to exhibit a BIC mode for infrared light, and including a perovskite material.

### BRIEF DESCRIPTION OF DRAWINGS

FIG. 1 is a schematic diagram illustrating an example of a configuration of a laser device according to the present disclosure.

FIG. 2A is a schematic diagram illustrating an example of a configuration of a laser light generating unit.

FIG. 2B is a schematic diagram of assistance in explaining an air hole array structure.

FIG. 2C is a schematic diagram of assistance in explaining the air hole array structure.

FIG. 2D is a schematic diagram of assistance in explaining an out-of-plane type laser light generation.

FIG. 3A is a schematic diagram illustrating an example of a configuration of a laser light generating unit.

FIG. 3B is a schematic diagram of assistance in explaining an example of a nanostructure.

FIG. 3C is a schematic diagram of assistance in explaining an example of a nanostructure.

FIG. 3D is a schematic diagram of assistance in explaining an in-plane type laser light generation.

FIG. 4A is a schematic diagram illustrating an example of a configuration of a laser light generating unit.

FIG. 4B is a schematic diagram illustrating an example of a configuration of a laser light generating unit.

FIG. 5 is a diagram illustrating an example of a configuration of an optical circuit chip.

FIG. 6A is a schematic diagram illustrating a laser light generating unit for which a simulation is performed.

FIG. 6B is a schematic diagram illustrating the laser light generating unit for which the simulation is performed.

FIG. 7 is a diagram illustrating a result of simulation for the laser light generating unit.

FIG. 8 is a diagram illustrating a result of simulation for the laser light generating unit.

### DESCRIPTION OF EMBODIMENTS

Preferred embodiments of the present disclosure will hereinafter be described. The embodiments to be described in the following represent an example of representative embodiments of the present disclosure, and the present disclosure is not limited only to these embodiments. In addition, these embodiments may be combined with each other.

Incidentally, the description of the present disclosure will be made in the following order.
1. First Embodiment (Laser Device)
1.1 Outline of Present Disclosure
1.2 Laser Device
1.2.1 Example of Configuration
1.2.2 Example of Configuration of Laser Light

Generating Unit Having Array Structure of Two-Dimensionally Arranged Air Holes
1.2.3 BIC Mode
1.2.4 Zero Refractive Index
1.2.5 Emitted Laser Light
1.2.6 Laser Light Generating Unit Having Air Hole

Array Structure in which Air Holes are Arranged One-Dimensionally
1.3 Modifications
2. Second Embodiment (Laser Light Generating Unit)
3. Third Embodiment (System)
4. Fourth Embodiment (Metamaterial)
5. Examples
5.1 First Example
5.2 Second Example

### 1. FIRST EMBODIMENT (LASER DEVICE)

### 1.1 Outline of Present Disclosure

The present disclosure provides a laser device including a laser light generating unit that oscillates infrared light. The laser light generating unit has a nanostructure configured to exhibit a BIC mode, and includes a perovskite material. The thus configured laser light generating unit can oscillate laser light in an infrared region (for example, light in a communication wavelength band), and further has a low laser oscillation threshold value and can reduce an optical loss. Further, the laser light generating unit can also achieve a high Q-value.

In a particularly preferable embodiment, the laser light generating unit may include a nanostructure configured to exhibit the BIC mode and exhibit a zero refractive index. It is thereby possible to realize, for example, a laser device not having a laser cavity.

The laser device according to the present disclosure (laser light generating unit in particular) may be one that does not have a laser cavity. For example, an ordinary laser has a resonator (pair of mirrors) as the laser cavity. The laser device according to the present disclosure does not need to have the resonator. The laser device according to the present disclosure may be one that does not have the pair of mirrors constituting the resonator.

The exhibition of the zero refractive index means that a wavelength is infinite in the laser light generating unit in which light is wave-guided. This means that the size (corresponding to a cavity length in the case of ordinary laser light) of the laser light generating unit as a whole can be designed without depending on the wavelength. The size of the laser light generating unit as a whole can therefore be designed freely. This contributes also to the miniaturization of the laser device, for example.

The laser light generating unit may have a gain medium unit including the perovskite material. The gain medium unit has the nanostructure described above. That is, the gain medium unit has the nanostructure configured to exhibit the BIC mode. Preferably, the gain medium unit has the nanostructure configured to exhibit the BIC mode and exhibit the zero refractive index.

In one embodiment, the nanostructure itself included in the gain medium unit may be formed by the perovskite material.

In another embodiment, the nanostructure included in the gain medium unit may be formed by a dielectric material (for example, a Si material). In this case, the nanostructure formed by the dielectric material may be embedded in the perovskite material. That is, in this embodiment, the nanostructure may be embedded in a medium including the perovskite material.

The perovskite material may be a material that generates light in the infrared region by photoluminescence, may be particularly a material that generates light in a near-infrared region or a mid-infrared region, or may be more particularly a material that generates light in the near-infrared region.

The perovskite material can be manufactured with ease and at a low cost as compared with, for example, a semiconductor material (as compared with, for example, GaN, InP, GaAs, and the like). In addition, as compared with the semiconductor material, the perovskite material has a higher light absorption characteristic and has a more efficient light emission characteristic, and further has a lower laser threshold value. In addition, as compared with the semiconductor material, the perovskite material can generate light of various wavelengths when the material is adjusted. Thus, the laser light generating unit including the perovskite material has an excellent laser light generation characteristic.

The perovskite material may be an organic-inorganic perovskite material, for example.

The perovskite material may be a perovskite material expressed by a composition formula AMX₃, for example. In the composition formula, A is a monovalent cation, M is a divalent cation, and X is a monovalent anion.

Examples of the monovalent cation A the above-described A include an alkali metal cation or a monovalent organic cation. The above-described A may be, for example, methylammonium cation (CH₃NH₃⁺), a formamidinium cation (NH₂CHNH₂⁺), or a cesium cation (Cs⁺).

The divalent cation of the above-described M may be a Pb cation or a Sn cation, for example.

The monovalent anion of the above-described X may be a halogen anion, for example.

The perovskite material may be CH₃NH₃PbI₃ (referred to also as “MAPbI₃”), for example.

The nanostructure may be configured to exhibit the BIC mode, and may be particularly preferably configured to exhibit the BIC mode and exhibit the zero refractive index. An air hole array structure, for example, can be cited as the nanostructure that exhibits both the BIC mode and the zero refractive index. The air hole array structure may be a structure having air holes arranged in a material forming the nanostructure, or may be preferably a structure in which air holes having a predetermined shape are arranged one-dimensionally or two-dimensionally. That is, the nanostructure may be a structure in which structural units having air holes are arranged one-dimensionally or two-dimensionally.

Because the laser light generating unit includes the perovskite material, the laser light generating unit can have a low laser oscillation threshold value. Such a low laser oscillation threshold value is considered to be attributable to a highly efficient absorption and a high radiation coefficient of the perovskite material.

In addition, because the laser light generating unit exhibits the BIC mode, the laser light generating unit can achieve a high Q-value. Because the laser light generating unit exhibits the BIC mode, the laser light generating unit can avoid a leaky mode.

In addition, the laser light generating unit oscillates infrared laser light.

An existing BIC mode exhibiting laser that uses perovskite operates only at visible light wavelengths. It is difficult to apply such a laser to optical communication or LiDAR that uses near-infrared light.

The laser light generating unit operates with infrared light, particularly near-infrared light, and is therefore considered to have high value for industrial application particularly in optical communication.

In a preferable embodiment, because the laser light generating unit exhibits the zero refractive index, the laser light generating unit contributes to the miniaturization of the laser device. The laser device including the laser light generating unit is suitable for on-chip implementation, for example.

In a preferable embodiment, the laser light generating unit has an air hole array structure. The structure is mechanically robust, and can therefore be mounted on a CMOS platform, for example. For example, the laser light generating unit can be easily mounted on an optical circuit.

### 1.2 Laser Device

### 1.2.1 Configuration Example

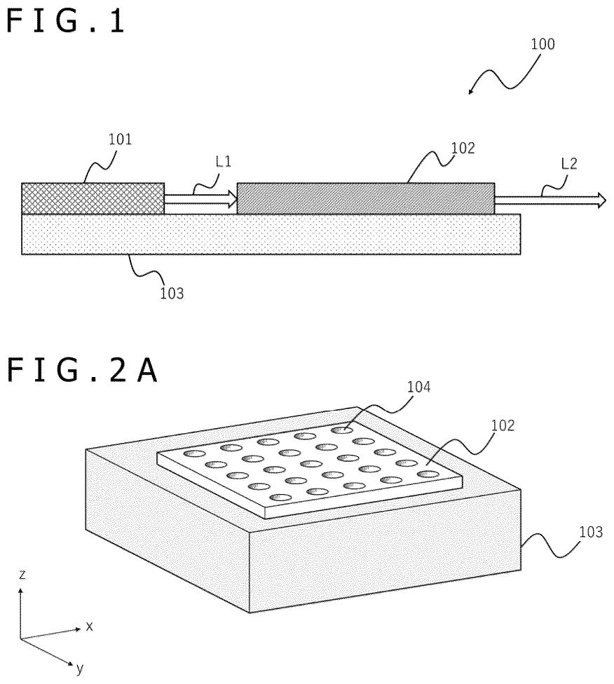

A laser device according to the present disclosure will be described with reference to FIG. 1. The figure illustrates an example of a schematic configuration of the laser device according to the present disclosure. The laser device 100 according to the present disclosure illustrated in the figure includes a light source 101 and a laser light generating unit 102. As illustrated in the figure, the light source and the laser light generating unit may be provided on a substrate 103, for example. The figure schematically illustrates a section perpendicular to the substrate 103 in the form of a block diagram, and actual dimensions or shapes do not have to be according to the figure.

The light source 101 emits exciting light L1. The light source and the laser light generating unit are configured such that the exciting light L1 reaches the laser light generating unit 102.

The light source 101 may be an LED or a laser, for example, but is not limited to these. The configuration of the light source 101 may be selected as appropriate by a person skilled in the art according to the exciting light L1 desired for laser light generation.

The exciting light L1 includes light of a wavelength that causes photoluminescence (PL) by a perovskite material included in the laser light generating unit 102. The light source 101 is configured to emit the exciting light L1 including the light of the wavelength.

The exciting light L1 includes, for example, light of wavelengths of 300 to 600 nm, preferably includes light of wavelengths of 330 to 550 nm, and more preferably includes light of wavelengths of 350 to 500 nm. The exciting light L1 may be light of a single wavelength in any one of these numerical ranges. The perovskite material exhibits a higher absorption efficiency for the exciting light having a shorter wavelength. Thus, laser oscillation efficiency can be improved by the exciting light having a shorter wavelength.

The exciting light L1 emitted from the light source 101 reaches the laser light generating unit 102. In particular, the exciting light L1 reaches the perovskite material included in the laser light generating unit 102. Photoluminescence (hereinafter referred to also as PL) is caused by irradiating the perovskite material with the exciting light L1, and thereby infrared light is generated. A space (for example, air) may be present between the light source 101 and the laser light generating unit 102. The laser device may be configured such that the exciting light L1 reaches the laser light generating unit 102 via the space.

The laser light generating unit 102 has a nanostructure configured to exhibit the BIC mode. The nanostructure may be configured to exhibit the BIC mode for light of a predetermined wavelength. That is, the nanostructure may be configured to exhibit the BIC mode in a case where the exciting light L1 reaches the nanostructure, particularly in a case where the light of the wavelength described with regard to the exciting light L1 in the above description reaches the nanostructure.

The exhibition of the BIC mode can prevent the light of the predetermined wavelength from being radiated to the outside of the nanostructure, and make the light of the predetermined wavelength locally exist within the nanostructure.

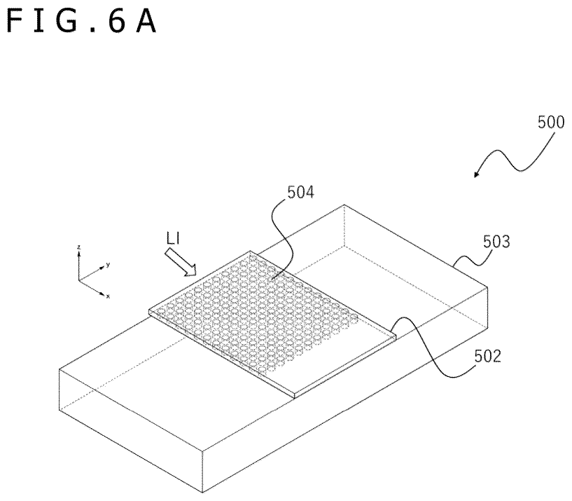

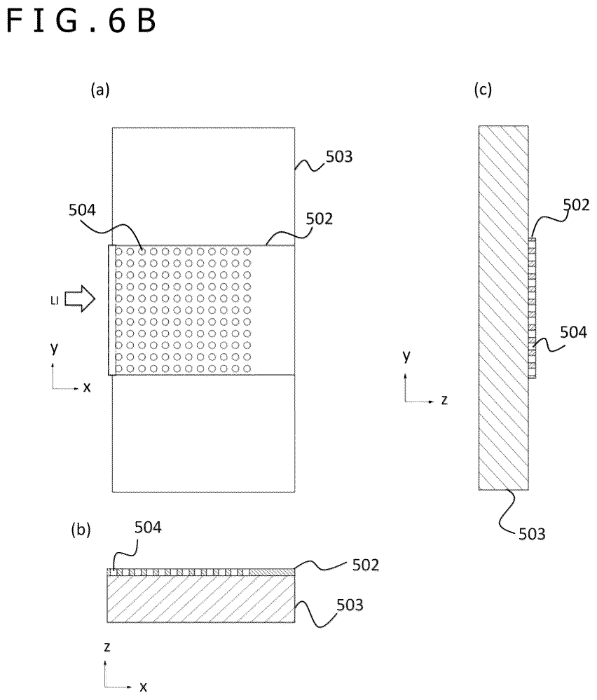

The laser light generating unit 102 emits laser light L2 generated in the laser light generating unit. In the figure, as illustrated in a subsequent embodiment (FIGS. 6A and 6B in particular), the exciting light L1 traveling in parallel with an air hole array surface of the nanostructure enters the laser light generating unit 102, and then the laser light L2 is emitted as an in-plane type from the laser light generating unit 102. Thus, the laser device according to the present disclosure may be an in-plane type laser device.

In a case where the laser device according to the present disclosure is an in-plane type (or on-chip type) laser device, the light source and the laser light generating unit may be arranged such that the exciting light traveling in parallel with the air hole array surface of the nanostructure enters the laser light generating unit. However, the light source and the laser light generating unit may be arranged such that the exciting light perpendicularly enters the array surface of the nanostructure of the laser light generating unit. An in-plane type laser light emission is easily realized by making the exciting light enter the laser light generating unit in parallel with the air hole array surface of the nanostructure. Thus, the laser device is easily used as an on-chip type, and is easily used as a constituent element of an optical circuit chip, for example.

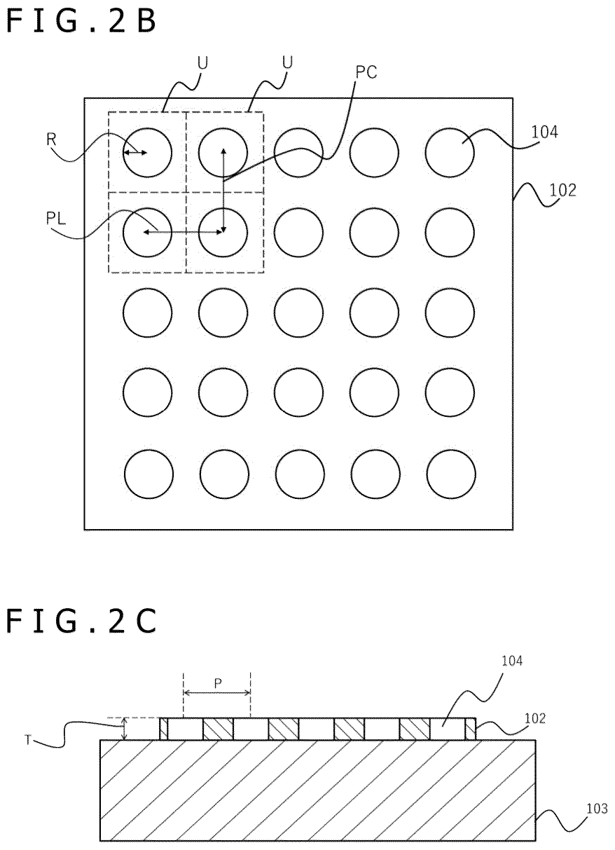

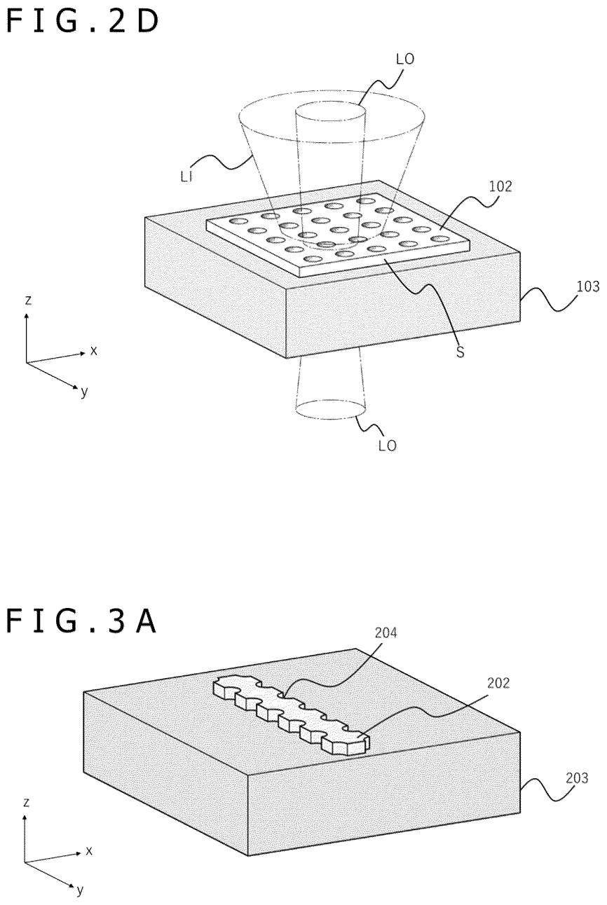

In addition, the laser device according to the present disclosure may be an out-of-plane type laser device. The out-of-plane type laser device can output laser light as illustrated in FIG. 2D to be described later, for example.

In a case where the laser device according to the present disclosure is an out-of-plane type laser device, the light source and the laser light generating unit may be arranged such that the exciting light perpendicularly enters the array surface of the nanostructure of the laser light generating unit. However, the light source and the laser light generating unit may be arranged such that the exciting light traveling in parallel with the air hole array surface of the nanostructure enters the laser light generating unit. When the light source and the laser light generating unit are arranged such that the exciting light perpendicularly enters the array surface of the nanostructure of the laser light generating unit, an out-of-plane optical output such as that of a vertical cavity surface emitting laser is easily realized.

The laser light generating unit 102 may more preferably have a nanostructure configured to exhibit the BIC mode and exhibit a zero refractive index. An example of a configuration of the laser light generating unit 102 will be described later in more detail.

The material of the substrate 103 may be SiO₂, for example, but is not limited to this. The material of the substrate may be, for example, any one of CaF₂, Al₂O₃, and various kinds of metal oxides. These materials are suitable for the exhibition of the BIC mode and/or the exhibition of the zero refractive index, for example, for infrared light, particularly for near-infrared light and mid-infrared light, more particularly for near-infrared light.

### 1.2.2 Example of Configuration of Laser Light Generating Unit Having Array Structure of Two-Dimensionally Arranged Air Holes

An example of a configuration of the laser light generating unit 102 will be described with reference to FIG. 2A. The figure is a schematic perspective view of the laser light generating unit 102. The laser light generating unit 102 illustrated in the figure may be provided on the substrate 103. As illustrated in the figure, the laser light generating unit 102 may be a layer of the perovskite material. That is, in the present disclosure, the nanostructure may be formed by the perovskite material.

The layer is provided with multiple air holes 104. As illustrated in the figure, the air holes 104 are arranged two-dimensionally in the layer, and are particularly arranged so as to form multiple rows and columns at predetermined intervals. The laser light generating unit 102 thus has a nanostructure in which the multiple air holes are arranged. Within the present specification, the nanostructure in which the air holes are arranged will be referred to also as an air hole array structure.

The perovskite material exerts a function as a gain medium. That is, the laser light generating unit 102 has the substrate 103 and a gain medium layer provided on the substrate.

The air hole array structure will be described with reference to FIG. 2B. The figure is a top view of the laser light generating unit 102. As illustrated in the figure, the multiple air holes 104 are two-dimensionally and regularly arranged in the laser light generating unit 102. As illustrated in the figure, the shape of each air hole (particularly the shape of an opening portion of each air hole) may preferably be a circular shape, but may be an elliptic shape or another shape, for example. The other shape may be, for example, a polygon (for example, a triangular shape, a quadrangular shape, a pentagonal shape, a hexagonal shape, a heptangular shape, an octagonal shape, or the like).

In the figure, the air holes are present in five rows and five columns, that is, the number of air holes provided to each column and each row is five. However, this number is a number for the convenience of description of the present disclosure. The number of air holes actually provided may be more than this number. The number of air holes may be changed as appropriate according to, for example, the size of the laser light generating unit and the size and arrangement period of the air holes.

The number of air holes included in each row of the air hole array structure is not limited to the number (five) illustrated in the figure, and may be, for example, equal to or more than two, or may preferably be equal to or more than three, equal to or more than four, or equal to or more than five. The periodic arrangement of the air holes contributes to the exhibition of the zero refractive index. An upper limit of the number of the arranged air holes does not need to be limited to any number, and may be, for example, equal to or less than 10,000, equal to or less than 5,000, equal to or less than 1,000, equal to or less than 500, or equal to or less than 100.

As in each row, the number of air holes included in each column of the air hole array structure is not limited to the number (five) illustrated in the figure, and may be, for example, equal to or more than two, or may preferably be equal to or more than three, equal to or more than four, or equal to or more than five. The periodic arrangement of the air holes contributes to the exhibition of the zero refractive index. An upper limit of the number of the arranged air holes does not need to be limited to any number, and may be, for example, equal to or less than 10,000, equal to or less than 5,000, equal to or less than 1,000, equal to or less than 500, or equal to or less than 100.

A radius R of the air holes 104 may be, for example, equal to or more than 10 nm, preferably equal to or more than 15 nm, more preferably equal to or more than 20 nm, even more preferably equal to or more than 30 nm, equal to or more than 40 nm, or equal to or more than 50 nm, or may be even more preferably equal to or more than 60 nm, equal to or more than 70 nm, or equal to or more than 80 nm.

The radius R of the air holes 104 may be, for example, equal to or less than 300 nm, preferably equal to or less than 290 nm, more preferably equal to or less than 280 nm, equal to or less than 270 nm, or equal to or less than 260 nm, or may be even more preferably equal to or less than 250 nm, equal to or less than 240 nm, equal to or less than 230 nm, equal to or less than 220 nm, equal to or less than 210 nm, or equal to or less than 200 nm.

A numerical range of the radius R of the air holes 104 may be selected from the upper limit values and the lower limit values provided in the above description, and may be, for example, 10 to 300 nm, 30 to 280 nm, or 50 to 250 nm.

An arrangement period PL in a row direction of the air holes and an arrangement period PC in a column direction thereof may be the same length or may be different lengths. Preferably, the arrangement period PL and the arrangement period PC are substantially the same dimension.

Within the present specification, in a case where the arrangement period PL and the arrangement period PC are substantially the same dimension, each of these two values may be referred to as an arrangement period P.

Any one of the row direction and the column direction may be parallel with a propagation direction of light within the nanostructure, and the other direction is perpendicular to the propagation direction of the light within the nanostructure. A state in which one of the two arrangement directions of the air holes is parallel with the propagation direction of the light and the other is perpendicular to the propagation direction of the light contributes to the exhibition of the zero refractive index and/or the BIC mode.

The arrangement period PL in the row direction of the air holes 104 is, for example, equal to or more than 100 nm, preferably equal to or more than 200 nm, more preferably equal to or more than 300 nm, even more preferably equal to or more than 350 nm, may be even more preferably equal to or more than 400 nm, equal to or more than 450 nm, or equal to or more than 500 nm, or may be equal to or more than 600 nm, equal to or more than 700 nm, or equal to or more than 800 nm in some embodiments.

The arrangement period PL in the row direction of the air holes 104 may be preferably equal to or less than 2500 nm, more preferably equal to or less than 2000 nm, even more preferably equal to or less than 1500 nm, equal to or less than 1400 nm, equal to or less than 1300 nm, equal to or less than 1200 nm, equal to or less than 1100 nm, or equal to or less than 1000 nm.

A numerical range of the arrangement period PL in the row direction may be selected from the upper limit values and the lower limit values provided in the above description, and is, for example, 100 to 2500 nm or may be 100 to 2000 nm or 100 to 1000 nm.

The arrangement period PC in the column direction of the air holes 104 is, for example, equal to or more than 100 nm, preferably equal to or more than 200 nm, more preferably equal to or more than 300 nm, even more preferably equal to or more than 350 nm, may be even more preferably equal to or more than 400 nm, equal to or more than 450 nm, or equal to or more than 500 nm, or may be equal to or more than 600 nm, equal to or more than 700 nm, or equal to or more than 800 nm in some embodiments.

The arrangement period PC in the column direction of the air holes 104 may be preferably equal to or less than 2500 nm, more preferably equal to or less than 2000 nm, even more preferably equal to or less than 1500 nm, equal to or less than 1400 nm, equal to or less than 1300 nm, equal to or less than 1200 nm, equal to or less than 1100 nm, or equal to or less than 1000 nm.

A numerical range of the arrangement period PC in the column direction may be selected from the upper limit values and the lower limit values provided in the above description, and is, for example, 100 to 2500 nm or may be 100 to 2000 nm or 100 to 1000 nm.

As illustrated in the figure, the arrangement period PL and the arrangement period PC may refer to a pitch at which structural units U are arranged, and may be an interval between centers of air holes, for example. A structural unit U is a structural unit of the nanostructure, as illustrated in the figure, for example, and may refer to a minimum structural unit having one air hole, as illustrated in the figure.

Adjustment of the radius R and the arrangement periods PL and PC of the air holes to within the above-described numerical ranges contributes to making the nanostructure exhibit the zero refractive index. In addition, the radius R and the arrangement periods PL and PC may be adjusted as appropriate according to the wavelength of incident light entering the laser light generating unit or the wavelength of the laser light.

As described above, the nanostructure may be a structure in which the structural units having an air hole are arranged two-dimensionally. In one embodiment, the radius of the air holes may be 10 to 300 nm, and the arrangement period of the air holes may be 100 to 1000 nm.

As illustrated in FIG. 2C, the nanostructure (gain medium layer in particular) of the laser light generating unit 102 has a thickness T. In a case where the shape of opening portions of the air holes is a circular shape, the air holes may be air holes in a cylindrical shape, and the thickness T corresponds to the height of the cylindrical shape.

The thickness T of the nanostructure is, for example, equal to or more than 100 nm, preferably equal to or more than 200 nm, more preferably equal to or more than 300 nm.

The thickness T of the nanostructure may be preferably equal to or less than 1500 nm, more preferably equal to or less than 1400 nm, even more preferably equal to or less than 1300 nm, equal to or less than 1200 nm, equal to or less than 1100 nm, or equal to or less than 1000 nm.

A numerical range of the thickness T may be selected from the upper limit values and the lower limit values provided in the above description, and is, for example, 100 to 1500 nm, or may be 200 to 1300 nm or 300 to 1000 nm.

Adjustment of the thickness T within the above-described numerical ranges contributes to making the nanostructure exhibit the BIC mode. In addition, the thickness T may be adjusted as appropriate according to the wavelength of the incident light entering the laser light generating unit or the wavelength of the laser light.

### 1.2.3 BIC Mode

The BIC (Bound state in the continuum) mode is referred to also as a mode of a bound state in a continuum. The BIC may refer to a state in which a wave existing in a specific energy region is spatially bound and confined. The BIC can, for example, appear as a mode in which light is confined in a photonic crystal in a frequency region in which the light should leak out of the crystal.

In the present disclosure, the BIC mode exhibited by the nanostructure may be preferably a BIC mode of a resonance-trapped type (resonance-trapped BIC) or a BIC mode of a symmetry-protected type (symmetry-protected BIC), or may be particularly preferably the BIC mode of the resonance-trapped type. The BIC mode of the resonance-trapped type can be exhibited in an air hole array type nanostructure, for example. The BIC mode can be exhibited by adjusting the thickness of the nanostructure, for example. In addition, the BIC mode of the symmetry-protected type can be realized by a nanostructure similar to that of the BIC mode of the resonance-trapped type. The size (the air hole radius, the period, and the thickness) of each element in the nanostructure may be adjusted as appropriate by a person skilled in the art according to a desired BIC mode.

The BIC mode of the resonance-trapped type may mean that two modes (wave resonance) bring about a perfect destructive interference at a certain position. The BIC mode of the resonance-trapped type is described in Kodigala, A., Lepetit, T., Gu, Q., Bahari, B., Fainman, Y., & Kante, B. (2017). Lasing action from photonic bound states in continuum. Nature, 541 (7636), 196-199., for example. Light in the two modes as leaky modes is normally emitted out of the plane. This can be a cause of a high optical loss. In a case where a specific structure is adopted for a specific wavelength, a perfect destructive interference is realized between the two modes. Consequently, light of the specific wavelength cannot be emitted out of the plane, and is confined within the nanostructure.

The BIC mode may be preferably a BIC mode exhibited for infrared light, may be particularly a BIC mode exhibited for near-infrared light or mid-infrared light, or may be more particularly a BIC mode exhibited for near-infrared light. More particularly, the BIC mode may be a BIC mode exhibited for light of a specific wavelength or light in a specific wavelength range in the infrared light.

The nanostructure that exhibits the BIC mode binds the infrared light within the nanostructure, and emits other light from the nanostructure. This enables laser light generation in an infrared region.

The laser light generating unit 102 may more preferably have a nanostructure configured to exhibit the BIC mode and exhibit the zero refractive index. The nanostructure may be preferably configured to exhibit the zero refractive index for infrared light, and may be particularly configured to exhibit the zero refractive index for light of a specific wavelength.

(Design of Structure that Exhibits BIC Mode)

The BIC mode, particularly the BIC mode of the resonance-trapped type, can be exhibited by adjusting the thickness T of the nanostructure.

For example, when the nanostructure that exhibits the zero refractive index in a case of a predetermined initial thickness value Ts is identified as described below, the air hole radius R and the arrangement period P of the air hole array structure can be identified. Then, the thickness at which the BIC mode is exhibited can be identified by changing (for example, increasing or decreasing) the thickness of the nanostructure in the case of the identified air hole radius R and the identified arrangement period P.

Incidentally, the air hole radius R and the arrangement period P may also be adjusted as the thickness of the nanostructure is changed. The zero refractive index can be exhibited even when the air hole radius R and the arrangement period P identified for the exhibition of the zero refractive index are changed.

### 1.2.4 Zero Refractive Index

Within the present specification, the “zero refractive index” means that the absolute value of a refractive index n is less than 0.1. That is, the zero refractive index is expressed by the following Expression (1).

$$\begin{matrix}[ Math . 1 ] & \\ \vert n \vert < 0.1 & ( 1 )\end{matrix}$$

A bandwidth of wavelengths in which the nanostructure exhibits the zero refractive index is, for example, equal to or more than 20 nm, preferably equal to or more than 30 nm, may be more preferably equal to or more than 40 nm, equal to or more than 50 nm, or equal to or more than 60 nm, or may be even more preferably equal to or more than 70 nm, equal to or more than 75 nm, or equal to or more than 80 nm. Further, the bandwidth may be equal to or more than 100 nm, equal to or more than 110 nm, equal to or more than 120 nm, or equal to or more than 130 nm.

In addition, an upper limit value of the bandwidth of the wavelengths in which the nanostructure exhibits the zero refractive index does not have to be particularly identified, but may be, for example, equal to or less than 300 nm, equal to or less than 250 nm, equal to or less than 200 nm, equal to or less than 190 nm, equal to or less than 180 nm, or equal to or less than 170 nm.

The bandwidth of the wavelengths in which the nanostructure exhibits the zero refractive index may be selected from the upper limit values and the lower limit values provided in the above description, and may be, for example, equal to or more than 20 nm and equal to or less than 200 nm, equal to or more than 30 nm and equal to or less than 190 nm, or equal to or more than 40 nm and equal to or less than 180 nm.

The bandwidth of the wavelengths in which the nanostructure exhibits the zero refractive index is identified on the basis of the refractive index n measured in a case where light of each wavelength is made to enter the nanostructure. The bandwidth is a range of wavelengths as a range in which the refractive index n satisfies the above Expression (1).

A measuring method to be described in the following may be adopted as a method of measuring the refractive index n.

### (Refractive Index Measuring Method)

The refractive index n (referred to as “n” in this measuring method) of the nanostructure is measured according to a method described in Monolithic CMOS-compatible zero-index metamaterials, DARYL I. VULIS et al., Optics Express, 2017, 25 (11), 12381-12399. In the method, letting mi be the refractive index of a measurement target material (metamaterial), letting n₂ be the refractive index of a material adjacent to the measurement target material, letting θ₁ be an incidence angle, and letting θ₂ be an emission angle, the refractive index mi is determined from the following Expression (2) by a Snell's law.

$$\begin{matrix}[ Math . 2 ] & \\ {n}_{1} sin {θ}_{1} = {n}_{2} sin {θ}_{2} & ( 2 )\end{matrix}$$

(Design of Structure that Exhibits Zero Refractive Index)

The structure that exhibits the zero refractive index may be designed on the basis of a known method in the present technical field, for example. The structure may be designed by, for example, performing band calculation for the exhibition of a Dirac Cone mode.

Alternatively, the zero refractive index may be exhibited by making the wavelength of light propagating within the nanostructure and the structural unit period of the nanostructure coincide with each other. The present inventor has found that the zero refractive index can be exhibited by making the wavelength of the light propagating within the nanostructure and the structural unit period (for example, an air hole period) of the nanostructure coincide with each other. This method obviates a need for the band calculation for the exhibition of the Dirac Cone mode, which has been regarded as essential in the method in the past. It is therefore possible to design the nanostructure more easily.

In a case where the nanostructure is thus designed, at least the arrangement period of air holes in a direction parallel with the propagation direction of the light within the nanostructure is made to coincide with the wavelength of the light propagating within the nanostructure. Preferably, both of the arrangement period of the air holes in the direction parallel with the propagation direction of the light within the nanostructure and the arrangement period of air holes in a direction perpendicular to the propagation direction of the light are made to coincide with the wavelength of the light propagating within the nanostructure. That is, preferably, both the arrangement periods PL and PC may coincide with the wavelength of the light propagating within the nanostructure.

In addition, in order to make the zero refractive index exhibited in the nanostructure, it suffices for the structural unit period to coincide with the wavelength of the light propagating within the nanostructure. Therefore, a condition considered in the method in the past (for example, a relation between the air hole radius and the period or the like) does not need to be considered in the design of the nanostructure, and the zero refractive index can be exhibited at any air hole radius. Therefore, the nanostructure is more practical, and is advantageous also from a viewpoint of a manufacturing process.

The zero refractive index can be exhibited in a case where the nanostructure is formed by the perovskite material. In addition, the zero refractive index can also be exhibited in a case where the nanostructure is formed by a dielectric material.

The wavelength range (bandwidth) in which the zero refractive index is exhibited can be freely controlled according to the kind of the perovskite material or the dielectric material, and realization of the bandwidth according to various kinds of applications becomes possible.

As described above, the nanostructure can be made to exhibit the zero refractive index by making the arrangement period of the structural units coincide with the wavelength of the light propagating within the nanostructure. For example, the metamaterial exhibits the zero refractive index when the arrangement periods PL and PC of the structural units are substantially the same as a wavelength λ_{WG} Of the light propagating within the metamaterial. That is, the nanostructure exhibits the zero refractive index by satisfying a condition

$$“ Arrangement Period P = Wavelength {λ}_{WG} . ”$$

The wavelength λ_{WG} is the wavelength of the light propagating within the nanostructure. The wavelength λ_{WG} is normally shorter than that of the incident light incident on the nanostructure (that is, light before reaching the nanostructure).

Within the present specification, the arrangement periods PL and PC being “substantially the same” as the wavelength λ_{WG} includes not only these values being completely the same but also these values being close to each other such that the nanostructure can exhibit the zero refractive index (in particular, these values being close to each other such that the nanostructure can exhibit the zero refractive index for light of a specific wavelength).

(Wavelength of Light for which Zero Refractive Index is Exhibited)

The light for which the nanostructure exhibits the zero refractive index may be infrared light, may be particularly near-infrared light, mid-infrared light, or far-infrared light, or may be preferably near-infrared light or mid-infrared light. The nanostructure may exhibit the zero refractive index for such light, and may exhibit the zero refractive index particularly in a case where such light enters the nanostructure.

In one embodiment, the light for which the nanostructure exhibits the zero refractive index may be near-infrared light, that is, may be light having wavelengths of 800 to 2500 nm, and may be preferably light having wavelengths of 900 to 2400 nm, and more preferably light having wavelengths of 1000 to 2000 nm.

In one embodiment, the light for which the zero refractive index is exhibited may be, for example, light having wavelengths of 1200 to 1800 nm, is more preferably light having wavelengths of 1300 to 1700 nm, is even more preferably light having wavelengths of 1400 to 1700 nm, or may be particularly light having wavelengths of 1450 to 1650 nm.

In another embodiment, the light for which the nanostructure exhibits the zero refractive index may be mid-infrared light, or may be, for example, 2500 to 4000 nm.

Such light is suitable for making the nanostructure exhibit the zero refractive index. That is, the nanostructure may have a characteristic of exhibiting the zero refractive index in a case where such light enters the nanostructure.

The nanostructure may exhibit the zero refractive index for the light as described above (infrared light in particular) in a case where the light enters the nanostructure. Moreover, the wavelength of the light during propagation within the nanostructure may be shorter than the wavelengths described above. That is, the nanostructure can propagate the incident light made incident thereon as light having a wavelength shorter than the wavelength of the incident light. The zero refractive index can be exhibited when the arrangement period of the structural units (or a distance between the centers of air holes) of the nanostructure is substantially the same as the shorter wavelength.

### 1.2.5 Emitted Laser Light

The laser light generating unit may perform an in-plane type laser light generation or may perform an out-of-plane type laser light generation. That is, the laser device including the laser light generating unit may be an in-plane type laser device, or may be an out-of-plane type laser device.

The out-of-plane type laser light generation will be described with reference to FIG. 2D. The figure illustrates the laser light generating unit 102 illustrated in FIG. 2A. Incident light LI enters the laser light generating unit. The light source may be configured such that the incident light LI substantially perpendicularly enters the surface in which the air holes of the nanostructure are arranged (surface parallel with an x-axis and a y-axis), as illustrated in FIG. 2D. That is, the incident light LI may be light traveling along a Z-axis in the figure.

The laser light generating unit generates laser light LO by photoluminescence in response to the incidence of the incident light LI. As illustrated in FIG. 2D, the laser light LO is emitted substantially perpendicularly from the surface in which the air holes of the nanostructure are arranged (surface parallel with the x-axis and the y-axis). That is, the laser light LO travels along the Z-axis direction in the figure. The out-of-plane type laser light generation thus emits the laser light.

Alternatively, the laser light generating unit may perform the in-plane type laser light generation. In the laser light generation, as will be described in an embodiment to be described later, the laser light is emitted along the y-axis direction in FIG. 2D from a surface S of the laser light generating unit, for example.

1.2.6 Laser Light Generating Unit Having Air Hole Array Structure in which Air Holes are Arranged One-Dimensionally

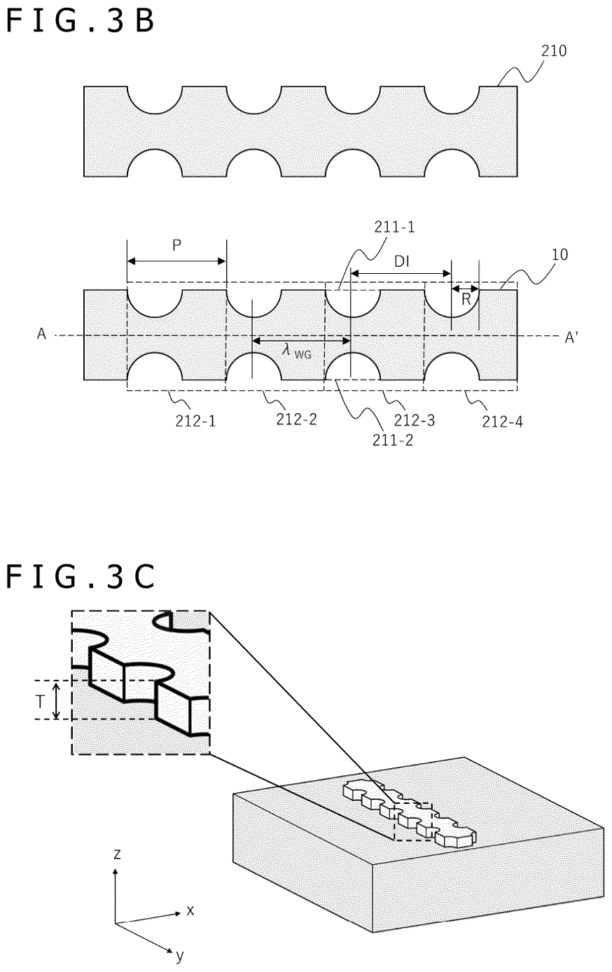

The laser light generating unit described above has the air hole array structure in which the structural units are arranged two-dimensionally. In the present disclosure, an air hole array structure in which structural units are arranged one-dimensionally may be adopted. The structure will be described with reference to FIG. 3A.

Such an air hole array structure in which air holes are arranged one-dimensionally can also exhibit the BIC mode. Further, the air hole array structure can also exhibit the zero refractive index. Moreover, the air hole array structure can generate laser light in the infrared region.

A laser light generating unit 202 illustrated in the figure may be provided on a substrate 203. As illustrated in the figure, the laser light generating unit 202 may be a layer of the perovskite material. That is, in the present disclosure, the nanostructure may be formed by the perovskite material.

Multiple air holes 204 are provided in the layer. The shape of the air holes 204 (particularly the shape of opening portions of the air holes) is a semicircular shape. As illustrated in the figure, the air holes 204 are arranged one-dimensionally, and are particularly arranged at predetermined intervals.

As for the number of air holes 204, in the figure, five air holes in the semicircular shape are arranged per side surface, and an air hole in a ¼ circular shape is provided to each end of the side surface. However, the number of air holes is not limited to five, and may be equal to or more than five. In addition, each end of the side surface may not be provided with the air hole in the ¼ circular shape. The number of air holes may be changed as appropriate according to, for example, the size of the laser light generating unit and the size and the arrangement period of the air holes.

The laser light generating unit 202 thus has a nanostructure in which multiple air holes are arranged. The nanostructure in which the air holes are thus arranged will be referred to also as an air hole array structure.

An example of the nanostructure will be described in the following with reference to FIG. 3B. The figure illustrates an example of a schematic configuration in which only a part of the nanostructure is extracted.

As illustrated in the figure, a nanostructure 210 includes multiple structural units 212 (structural units enclosed by dotted lines of 212-1 to 212-4), and these structural units are arranged one-dimensionally. The number of structural units included in the nanostructure is not limited to the number (four) illustrated in the figure, and may be, for example, equal to or more than two, or may be preferably equal to or more than three, equal to or more than four, or equal to or more than five. A periodic arrangement of the structural units contributes to the exhibition of the zero refractive index. An upper limit of the number of the arranged structural units does not need to be limited to any number, and may be, for example, equal to or less than 10,000, equal to or less than 5,000, equal to or less than 1,000, equal to or less than 500, or equal to or less than 100.

In addition, as illustrated at a left side end of the nanostructure 210 in the figure, a part of a structural unit in which part no air hole is formed may be present at an end of the nanostructure. For example, in a case where the nanostructure is configured as a waveguide in which structural units are arranged one-dimensionally, no air hole may be formed at both ends of the waveguide.

As illustrated in the figure, each structural unit 212 may have a rectangular shape. The rectangular may be a square shape, or may be an oblong shape. Each structural unit is provided with two air holes 211-1 and 211-2 having a semicircular shape, that is, two parts of a rectangular structure are chipped in a semicircular shape. These two air holes are provided to two sides parallel with a direction in which light is propagated among four sides constituting the rectangular shape. In addition, these two air holes are arranged at axisymmetric positions with respect to a central axis A-A′of the nanostructure.

Thus, the air holes in the structural units of the nanostructure have the shape of a divided circle. The shape of the divided circle may be, for example, a substantially semicircular shape.

Within the present specification, the “circle” may be a perfect circle, or may be an ellipse.

The substantially semicircular shape includes not only a semicircular shape divided such that a perfect circle or an ellipse is divided into two perfectly equal parts but also a semicircular shape divided by dividing a perfect circle or an ellipse into two substantially equal parts such that the nanostructure where the air holes in the substantially semicircular shape are included in the structural units can exhibit a desired function (the zero refractive index and/or the BIC mode).

The arrangement period P of the structural units is preferably equal to or more than 300 nm, more preferably equal to or more than 350 nm, may be even more preferably equal to or more than 400 nm, equal to or more than 450 nm, equal to or more than or 500 nm, or may be equal to or more than 600 nm, equal to or more than 700 nm, or equal to or more than 800 nm in some embodiments.

The arrangement period P of the structural units may be preferably equal to or less than 2500 nm, more preferably equal to or less than 2000 nm, even more preferably equal to or less than 1500 nm, equal to or less than 1400 nm, equal to or less than 1300 nm, equal to or less than 1200 nm, equal to or less than 1100 nm, or equal to or less than 1000 nm.

A numerical range of the arrangement period P may be selected from the upper limit values and the lower limit values provided in the above description, and is, for example, 300 to 2500 nm or may be 350 to 2000 nm or 400 to 1500 nm.

In a case where the shape of the structural units is a square shape or an oblong shape, for example, the arrangement period P can correspond to a dimension of the structural units in the arrangement direction (the length of one side of the square shape or the length of a long side or a short side of the oblong shape).

Incidentally, within the present specification, the “shape of the structural units” refers to the shape of the structural units assumed to be in a state of not being provided with the air holes.

The description of the numerical ranges mentioned with regard to the arrangement period P applies also to a dimension of the structural unit in a direction orthogonal to the arrangement direction.

In a case where the shape of the structural units is a square shape or an oblong shape, for example, the dimension of the structural units in the orthogonal direction may be the length of one side of the square shape or the length of a short side or a long side of the oblong shape.

The radius R of the air holes 212-1 and 212-2 may be, for example, equal to or more than 15 nm, preferably equal to or more than 20 nm, more preferably equal to or more than 30 nm, equal to or more than 40 nm, or equal to or more than 50 nm, or may be even more preferably equal to or more than 60 nm, equal to or more than 70 nm, or equal to or more than 80 nm.

The radius R of the air holes 212-1 and 212-2 may be, for example, equal to or less than 300 nm, preferably equal to or less than 290 nm, more preferably equal to or less than 280 nm, equal to or less than 270 nm, or equal to or less than 260 nm, or may be even more preferably equal to or less than 250 nm, equal to or less than 240 nm, equal to or less than 230 nm, equal to or less than 220 nm, equal to or less than 210 nm, or equal to or less than 200 nm.

A numerical range of the radius R of the air holes 212-1 and 212-2 may be selected from the upper limit values and the lower limit values provided in the above description, and may be, for example, 15 to 300 nm, 30 to 280 nm, or 50 to 250 nm.

An interval DI between the centers of two air holes adjacent to each other in the arrangement direction is preferably equal to or more than 300 nm, more preferably equal to or more than 350 nm, or may be even more preferably equal to or more than 400 nm, equal to or more than 450 nm, or equal to or more than 500 nm.

The interval DI may be preferably equal to or less than 2500 nm, more preferably equal to or less than 2000 nm, even more preferably equal to or less than 1500 nm, equal to or less than 1400 nm, equal to or less than 1300 nm, equal to or less than 1200 nm, equal to or less than 1100 nm, or equal to or less than 1000 nm.

The interval DI may be selected from the upper limit values and the lower limit values provided in the above description, and is, for example, 300 to 2500 nm or may be 350 to 2000 nm or 400 to 1500 nm. As described above, the interval DI may be substantially the same as the arrangement period P.

As described above, the nanostructure may be a structure in which the structural units having air holes are arranged one-dimensionally. In one embodiment, the radius of the air holes may be 10 to 300 nm, and the arrangement period of the air holes may be 100 to 1000 nm.

As described with regard to the array structure of the two-dimensionally arranged air holes in the above description, the arrangement period P may be substantially the same as the wavelength λ_{WG} of the light propagating within the nanostructure. The zero refractive index can be thereby exhibited.

As illustrated in FIG. 3C, the nanostructure may be provided on a substrate, for example, and the nanostructure may have a thickness T. The thickness T is a thickness in a direction orthogonal to flat surfaces of the structural units of the nanostructure (Z-axis direction in the figure).

The thickness T is preferably equal to or more than 50 nm, more preferably equal to or more than 60 nm, may be even more preferably equal to or more than 70 nm, equal to or more than 80 nm, equal to or more than 90 nm, or equal to or more than 100 nm, or may be particularly preferably equal to or more than 110 nm, equal to or more than 120 nm, equal to or more than 130 nm, equal to or more than 140 nm, or equal to or more than 150 nm.

The thickness T may be preferably equal to or less than 1000 nm, more preferably equal to or less than 950 nm, even more preferably equal to or less than 900 nm, equal to or less than 850 nm, equal to or less than 800 nm, equal to or less than 750 nm, or equal to or less than 700 nm.

The thickness T may be selected from the upper limit values and the lower limit values provided in the above description, and is, for example, 50 to 1000 nm or may be 100 to 900 nm or 150 to 800 nm.

With regard also to the laser light generating unit having the array structure of the one-dimensionally arranged air holes, the laser light generating unit may perform an in-plane type laser light generation, or may perform an out-of-plane type laser light generation.

The in-plane type laser light generation will be described with reference to FIG. 3D. The figure illustrates the laser light generating unit 202 illustrated in FIG. 3A, and incident light LI enters the laser light generating unit. The light source may be configured such that the incident light LI substantially perpendicularly enters the surface in which the air holes of the nanostructure are arranged (surface parallel with the x-axis and the y-axis), as illustrated in FIG. 3D. That is, the incident light LI may be light traveling along the z-axis direction in the figure.

The laser light generating unit generates laser light LOx and/or LOy by photoluminescence in response to the incidence of the incident light LI. As illustrated in FIG. 3D, the laser light LOx and/or LOy is emitted substantially horizontally from a surface that defines the thickness direction T of the laser light generating unit (surface perpendicular to the x-axis and the y-axis). That is, the laser light LO travels along the x-axis direction or the y-axis direction in the figure. The in-plane type laser light generation thus emits the laser light.

Incidentally, in the figure, arrows LOx and Loy are displayed such that the laser light is emitted in four directions. However, the laser light generating unit may emit the laser light in any one of the directions of these four arrows. In particular, the laser light generating unit can emit the laser light in any one of the directions of the two arrows LOy.

Alternatively, the laser light generating unit may perform the out-of-plane type laser light generation. As described with reference to FIG. 2D in the above description, the laser light generation emits the laser light along the z-axis direction.

1.3 Modifications

In another embodiment according to the present disclosure, the nanostructure included in the laser light generating unit is formed by a dielectric material, and the nanostructure may be provided in the perovskite material. In this embodiment, a photoluminescence of infrared light is generated by the perovskite material, and then the generated infrared light is emitted from the nanostructure.

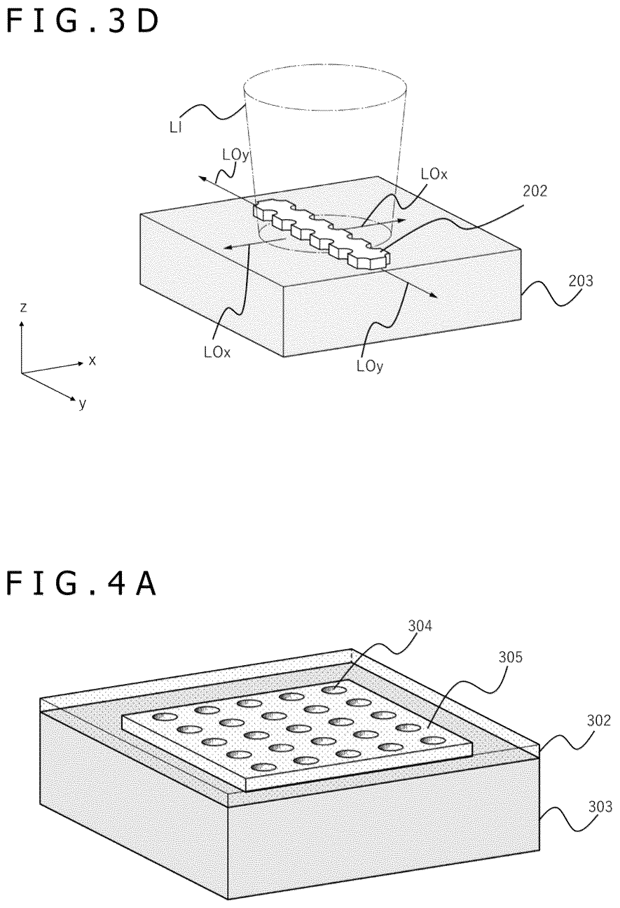

An example of a configuration of the laser light generating unit in this embodiment will be described with reference to FIG. 4A. The figure is a schematic perspective view of the laser light generating unit. The laser light generating unit 302 illustrated in the figure may be provided on a substrate 303. As illustrated in the figure, the laser light generating unit 302 may be a layer of the perovskite material, and a nanostructure 305 formed by the dielectric material is embedded in the layer. A semiconductor of Si, for example, may be used in place of the dielectric material. However, there is no limitation to this.

The nanostructure 305 is formed in a layer shape, and is provided with multiple air holes 304. As illustrated in the figure, the air holes 304 are arranged two-dimensionally, and are particularly arranged so as to form multiple rows and columns at predetermined intervals. The laser light generating unit 302 thus has an air hole array structure in which the multiple air holes are arranged.

The air hole array structure has a configuration as described with reference to FIG. 2B and FIG. 2C in the above 1.2, and the description thereof applies also to the present embodiment. For example, the radius R and the arrangement periods PL and PC of the air holes as well as the thickness T are as described in the above 1.2.

Another example of the configuration of the laser light generating unit in this embodiment will also be described with reference to FIG. 4B. The figure is a schematic perspective view of the laser light generating unit. The laser light generating unit 402 illustrated in the figure may be provided on a substrate 403. As illustrated in the figure, the laser light generating unit 402 may be a layer of the perovskite material, and a nanostructure 405 formed by a dielectric material is embedded in the layer. A semiconductor of Si, for example, may be used in place of the dielectric material. However, there is no limitation to this.

The nanostructure 405 is formed in a layer shape, and air holes 404 in a divided circular shape are arranged one-dimensionally in the nanostructure 405. The laser light generating unit 402 thus has an air hole array structure in which the multiple air holes are arranged.

The dielectric material may be, for example, any one of the following materials:
Si-based material (material having Si as one of main components thereof), for example, Si, Si₃N₄, SiO₂, and the like;
Ge-based material (material having Ge as one of main components thereof), for example, Ge and the like;
Ca-based material (material having Ca as one of main components thereof), for example, CaF₂ and the like;
Sn-based material (material having Sn as one of main components thereof), for example, Sn and the like;
Ga-based material (material having Ga as one of main components thereof), for example, GaN, GaAs, and the like;
In-based material (material having In as one of main components thereof), for example, InN, InP, and the like;
Cd-based material (material having Cd as one of main components thereof), for example, CdSe, CdS, and the like;
Zn-based material (material having Zn as one of main components thereof), for example, ZnSe and the like; or
Ti-based material (material having Ti as one of main components thereof), for example, Ti₂ and the like.

The dielectric material may be selected according to a desired bandwidth, for example.

In a preferable embodiment, the dielectric material may be the Si-based material or the Ge-based material, and is particularly preferably the Si-based material.

### 2. SECOND EMBODIMENT (LASER LIGHT GENERATING UNIT)

The present disclosure also provides a laser light generating unit that generates laser light in the infrared region. The laser light generating unit corresponds to the laser light generating unit described in the above 1. That is, the laser light generating unit has a nanostructure configured to exhibit the BIC mode and includes the perovskite material. The nanostructure, the BIC mode, and the perovskite material are as described in the above 1, and the description thereof applies also to the present embodiment.

Preferably, the nanostructure is as described in the above 1, and may exhibit the zero refractive index. The zero refractive index is as described in the above 1, and the description thereof applies also to the present embodiment.

### 3. THIRD EMBODIMENT (SYSTEM)

The present disclosure also provides a system including the laser device described in the above 1 or the laser light generating unit described in the above 2. The system may be, for example, a photonic system or a sensing system.

The photonic system may be, for example, an optical communication system or an optical circuit system. The laser device can emit infrared laser light, and has, for example, a low laser oscillation threshold value and a small optical loss. The laser device is therefore suitable in the photonic system such as the optical communication system or the optical circuit system. The laser device may be incorporated on a CMOS platform, for example.

In addition, the nanostructure of the laser device may be configured to exhibit the zero refractive index. In this case, dimensions of the nanostructure (particularly a length for which light is wave-guided) can be set freely. The laser device is therefore easily introduced into the photonic system.

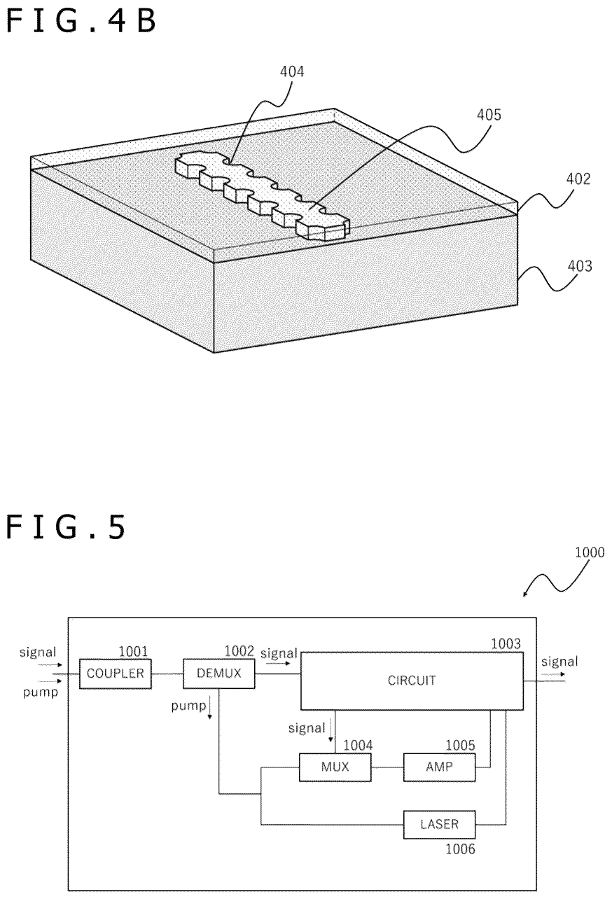

FIG. 5 is a schematic block diagram illustrating an example of a configuration of an optical circuit chip included in an optical circuit system according to the present disclosure. The optical circuit chip 1000 illustrated in the figure includes an optical coupler 1001, a demultiplexer 1002, an optical circuit 1003, a multiplexer 1004, an amplifier 1005, and a laser device 1006. These constituent elements may be connected to one another so as to be capable of optical transmission by photonic wire bonding indicated by lines connecting the respective elements in the figure. The laser device 1006 is the laser device according to the present disclosure as described in the above 1. These constituent elements 1001 to 1006 may be integrated on a chip, for example, and the chip may be a silicon on insulator (SOI) substrate, for example.

In the figure, pump light (pump) is the exciting light of the laser device, and signal light (signal) is a measured or read optical signal. The pump light and the signal light enter the optical circuit chip 1000 via an optical fiber, for example.

As illustrated in the figure, the optical circuit chip 1000 includes the coupler 1001, and the pump light and the signal light are introduced into the chip via the coupler 1001. That is, the coupler 1001 makes the pump light and the signal light introduced into the chip. It is thereby possible to prevent the occurrence of an optical loss at a time of the entrance into the chip from the optical fiber.

The demultiplexer 1002 demultiplexes the pump light and the signal light into waveguides in which the pump light and the signal light are to be propagated, respectively.

The optical circuit 1003 may be a passive element. The passive element may be, for example, a waveguide, a ring resonator, or a directional coupler.

The multiplexer 1004 guides the pump light and the signal light that have been demultiplexed to the same waveguide.

The amplifier 1005 amplifies the signal light. In a case where predetermined signal light enters the optical circuit chip, the predetermined signal light is amplified by the amplifier 1005.

The laser device 1006 generates laser light from the pump light. The laser light is transmitted to the optical circuit 1003.

The optical circuit chip may be thus configured. The optical circuit chip may be configured to perform signal processing in response to the signal light and/or the pump light. For example, the optical circuit chip may be configured to output predetermined output signal light in response to the input of the predetermined input signal light and/or pump light to the optical circuit chip. The laser device according to the present disclosure may be mounted on such an optical circuit chip. That is, in one embodiment, the optical circuit chip according to the present disclosure may include the laser device according to the present disclosure, the demultiplexer, the optical circuit, the multiplexer, and the amplifier.

The sensing system may be a light detecting system or a distance measuring system, for example, or may be particularly a LiDAR system. The laser device can emit laser light as near-infrared light, and is therefore suitable for use in such a sensing system that uses laser light in such a wavelength band.

### 4. FOURTH EMBODIMENT (METAMATERIAL)

The present disclosure also provides a metamaterial having the nanostructure configured to exhibit the BIC mode for infrared light. Preferably, the nanostructure may be configured to exhibit the zero refractive index for infrared light. The nanostructure is as described in the above 1, and the description thereof applies also in the present embodiment.

The metamaterial may, for example, include the perovskite material. For example, in one embodiment, the nanostructure may be formed by the perovskite material. In another embodiment, the nanostructure may be formed by the dielectric material, and the nanostructure may be embedded in the perovskite material.

The metamaterial according to the present disclosure may, for example, be used to control light in the infrared region or may be used to generate light in the infrared region. For example, the metamaterial may be incorporated in a photonic device (for example, an optical circuit, particularly an optical integrated circuit or the like), or may be incorporated in a sensing device.

### 5 EXAMPLES

### 5.1 First Example

For the laser light generating unit including the perovskite material, an electromagnetic field simulation was performed by using a finite-difference time-domain simulation as follows.

As illustrated in FIG. 2A, the laser light generating unit set as a target of the simulation included a nanostructure formed by the perovskite material and having an air hole array structure.

The laser light generating unit for which the simulation was performed is illustrated in FIG. 6A and FIG. 6B. FIG. 6A is a schematic perspective view of the laser light generating unit. FIG. 6B represents a schematic top view (a) in the xy plane of the laser light generating unit, a schematic side view (b) in the xz plane thereof, and a schematic side view (c) in the yz plane thereof. As illustrated in these figures, the laser light generating unit 500 is a nanostructure 502 having multiple air holes 504 arranged in the x-axis direction and the y-axis direction, and the nanostructure 502 is laminated on a substrate 503.

The substrate 503 was a Si₀₂ substrate, and the nanostructure 502 was MAPbI₃, which is a material that generates a strong photoluminescence (PL) of light in the vicinity of 800 nm.

In addition, as illustrated in these figures, the simulation simulated an electromagnetic field in a case where the incident light LI traveling in parallel with the x-axis direction was made incident on the nanostructure. As illustrated in these figures, the incident light is TE-polarized light (TE-polarized (y-axis) light), that is, the incident light is light traveling in parallel with the arrangement surface of an air hole array (light propagating in the X-axis direction), and an electric field oscillates in the y-axis direction.

The arrangement period P (Period) of the air holes, the air hole radius R (Radius), and the thickness T (Thickness) of the nanostructure were adjusted such that the nanostructure exhibited the zero refractive index. The zero refractive index was exhibited by adjusting these parameters by the adjustment as follows, for example.
Arrangement Period P: 430 nm
Air Hole Radius R: 124 nm
Thickness T: 245 nm
Wavelength of Light: 800 nm

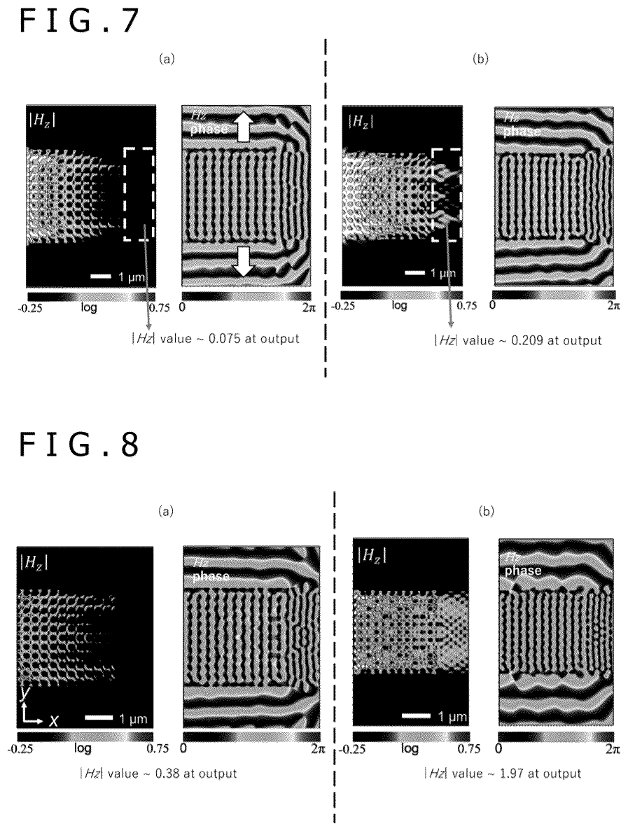

A simulation result with regard to the thus adjusted nanostructure is illustrated in (a) of FIG. 7. As indicated by two arrows extending in an upward-downward direction of the figure, a wave is perpendicularly separated from the surface of the nanostructure. This indicates that the refractive index of the air hole array structure is zero.

In addition, as indicated by a broken line in the figure, the Hz value of light emitted from the air hole array structure was approximately 0.075.

The thickness T of the air hole array structure that exhibited the zero refractive index was adjusted to realize the destructive interference of a radiation in the out-of-plane direction. For example, in a case of changing the thickness T to approximately twice as much and finely adjusting the arrangement period P and the radius R, and thereby setting these as follows, the zero refractive index was exhibited, and the BIC mode was exhibited.
Arrangement Period P: 400 nm
Air Hole Radius R: 115 nm
Thickness T: 560 nm
Wavelength of Light: 800 nm

A simulation result with regard to the thus adjusted air hole array structure is illustrated in (b) of FIG. 7. As illustrated in the figure, a wave is perpendicularly separated from the surface of the nanostructure. This indicates that the refractive index of the air hole array structure is zero.

Further, as indicated by a broken line in the figure, the |H_{z}| value of light emitted from the air hole array structure was approximately 0.209. That is, due to a decrease in a radiation loss of the BIC mode, the emitted light increased by 279% (=(0.209/0.075)*100).

The above results indicate that the nanostructure formed by the perovskite material can be made to exhibit both the zero refractive index and the BIC mode.

In addition, it is also indicated that an optical loss can be reduced by the exhibition of the BIC mode in addition to the zero refractive index. In addition, it is considered that because the optical loss is reduced, the laser oscillation threshold value can be lowered by adopting the nanostructure.

### 5.2 Second Example

A simulation similar to that of the first example was performed except that the material of the air hole array structure was changed to Si in place of MAPbI₃.

First, the arrangement period P of the air holes, the air hole radius R, and the thickness T of the gain medium layer were adjusted such that the air hole array structure formed by Si exhibited the zero refractive index. The zero refractive index was exhibited in a case where these parameters were adjusted as follows, for example, by the adjustment.
Arrangement Period P: 320 nm
Air Hole Radius R: 92 nm
Thickness T: 130 nm
Wavelength of Light: 800 nm

A simulation result with regard to the thus adjusted air hole array structure is illustrated in (a) of FIG. 8. As illustrated in the figure, a wave is perpendicularly separated from the surface of the nanostructure. This indicates that the refractive index of the air hole array structure is zero.

In addition, as indicated by a broken line in the figure, the |H_{z}| value of light emitted from the air hole array structure was approximately 0.38.

The thickness T of the air hole array structure that exhibited the zero refractive index was adjusted to realize the destructive interference of a radiation in the out-of-plane direction. For example, in a case of changing the thickness T to approximately twice as much and finely adjusting the arrangement period P and the radius R, and thereby setting these as follows, the zero refractive index was exhibited, and the BIC mode was exhibited.
Arrangement Period P: 265 nm
Air Hole Radius R: 66 nm
Thickness T: 250 nm
Wavelength of Light: 800 nm

A simulation result with regard to the thus adjusted air hole array structure is illustrated in (b) of FIG. 8. As illustrated in the figure, a wave is perpendicularly separated from the surface of the nanostructure. This indicates that the refractive index of the air hole array structure is zero.

Further, as indicated by a broken line in the figure, the |H_{z}| value of light emitted from the air hole array structure was approximately 1.97. That is, due to a decrease in a radiation loss of the BIC mode, the emitted light increased by 518% (=(1.97/0.38)*100).

The above results indicate that the nanostructure formed by Si can be made to exhibit both the zero refractive index and the BIC mode.

In addition, it is also indicated that an optical loss can be reduced by the exhibition of the BIC mode in addition to the zero refractive index. In addition, it is considered that because the optical loss is reduced, the laser oscillation threshold value can be lowered by adopting the nanostructure.

Incidentally, the present disclosure may also be configured as follows.

[1]

A laser device including:
a laser light generating unit having a nanostructure configured to exhibit a BIC mode and including a perovskite material, the laser light generating unit being configured to oscillate infrared light.
   [2]

The laser device according to [1], in which
the nanostructure is configured to exhibit a zero refractive index.
   [3]

The laser device according to [1] or [2], in which
the nanostructure is formed by the perovskite material, or
the nanostructure is formed by a dielectric material, and provided in the perovskite material.
   [4]

The laser device according to any one of [1] to [3], in which
the nanostructure is a structure in which structural units having air holes are arranged one-dimensionally or two-dimensionally.
   [5]

The laser device according to any one of [1] to [3], in which
the nanostructure is a structure in which structural units having air holes are arranged two-dimensionally,
the air holes have a radius of 10 to 300 nm, and
the air holes have an arrangement period of 100 to 1000 nm.
   [6]

The laser device according to any one of [1] to [3], in which
the nanostructure is a structure in which structural units having air holes are arranged one-dimensionally,
the air holes have a radius of 10 to 300 nm, and
the air holes have an arrangement period of 100 to 1000 nm.
   [7]

The laser device according to any one of [1] to [6], in which
the laser light generating unit has a substrate and a gain medium layer provided on the substrate, and
the gain medium layer has the nanostructure.
   [8]

The laser device according to any one of [1] to [6], in which
the laser light generating unit has a substrate and a gain medium layer provided on the substrate,
the gain medium layer has the nanostructure, and
the gain medium layer has a thickness of 100 to 1500 nm.
   [9]

The laser device according to any one of [1] to [8], in which
the perovskite material is an organic-inorganic perovskite material.

The laser device according to any one of [1] to [9], in which
the BIC mode is a BIC mode of a resonance-trapped type or a BIC mode of a symmetry-protected type.

The laser device according to any one of [1] to [10], in which
the laser device is a laser device of an in-plane type.

The laser device according to any one of [1] to [10], in which
the laser device is a laser device of an out-of-plane type.

An optical circuit system including:
the laser device according to any one of [1] to [12].

A sensing system including:
the laser device according to any one of [1] to [12].

A laser light generating unit having a nanostructure configured to exhibit a BIC mode and including a perovskite material, the laser light generating unit being configured to oscillate infrared light.

A metamaterial having a nanostructure configured to exhibit a BIC mode for infrared light, and including a perovskite material.

Embodiments and examples of the present disclosure have been concretely described above. However, the present disclosure is not limited to the foregoing embodiments and examples, and are susceptible of various kinds of modifications based on technical ideas of the present disclosure.

For example, configurations, methods, processes, shapes, materials, numerical values, and the like provided in the foregoing embodiments and examples are mere examples, and configurations, methods, processes, shapes, materials, numerical values, and the like different therefrom may be used as necessary. In addition, configurations, methods, processes, shapes, materials, numerical values, and the like in the foregoing embodiments and examples can be combined with one another unless departing from the spirit of the present disclosure.

In addition, in the present specification, a numerical range indicated by using “to” represents a range including numerical values described in front and in the rear of “to” as a minimum value and a maximum value, respectively. Among numerical ranges described stepwise in the present specification, an upper limit value or a lower limit value of a numerical range in a certain step may be replaced with an upper limit value or a lower limit value of a numerical range in another step.

### REFERENCE SIGNS LIST

100: Laser device
101: Light source
102: Laser light generating unit
103: Substrate

1. A laser device comprising:
a laser light generating unit having a nanostructure configured to exhibit a BIC mode and including a perovskite material, the laser light generating unit being configured to oscillate infrared light.

2. The laser device according to claim 1, wherein
the nanostructure is configured to exhibit a zero refractive index.

3. The laser device according to claim 1, wherein
the nanostructure is formed by the perovskite material, or
the nanostructure is formed by a dielectric material, and provided in the perovskite material.

4. The laser device according to claim 1, wherein
the nanostructure is a structure in which structural units having air holes are arranged one-dimensionally or two-dimensionally.

5. The laser device according to claim 1, wherein
the nanostructure is a structure in which structural units having air holes are arranged two-dimensionally,
the air holes have a radius of 10 to 300 nm, and
the air holes have an arrangement period of 100 to 1000 nm.

6. The laser device according to claim 1, wherein
the nanostructure is a structure in which structural units having air holes are arranged one-dimensionally,
the air holes have a radius of 10 to 300 nm, and
the air holes have an arrangement period of 100 to 1000 nm.

7. The laser device according to claim 1, wherein
the laser light generating unit has a substrate and a gain medium layer provided on the substrate, and
the gain medium layer has the nanostructure.

8. The laser device according to claim 1, wherein
the laser light generating unit has a substrate and a gain medium layer provided on the substrate,
the gain medium layer has the nanostructure, and
the gain medium layer has a thickness of 100 to 1500 nm.

9. The laser device according to claim 1, wherein
the perovskite material is an organic-inorganic perovskite material.

10. The laser device according to claim 1, wherein
the BIC mode is a BIC mode of a resonance-trapped type or a BIC mode of a symmetry-protected type.

11. The laser device according to claim 1, wherein
the laser device is a laser device of an in-plane type.

12. The laser device according to claim 1, wherein
the laser device is a laser device of an out-of-plane type.

13. An optical circuit system comprising:
the laser device according to claim 1.

14. A sensing system comprising:
the laser device according to claim 1.

15. A laser light generating unit having a nanostructure configured to exhibit a BIC mode and including a perovskite material, the laser light generating unit being configured to oscillate infrared light.

16. A metamaterial having a nanostructure configured to exhibit a BIC mode for infrared light, and including a perovskite material.
